(19) United States
(12) Patent Application Publication
(10) Pub. No.: US 2026/0303124 A1
(43) Pub. Date: Oct. 1, 2026

(54) METHODS FOR POLAR CODE DESIGN

(71) Applicant: Samsung Electronics Co., Ltd., Suwon-si (KR)

(72) Inventors: Heping Wan, Frisco, TX (US); Joonyoung Cho, Portland, OR (US)

(21) Appl. No.: 19/552,893

(22) Filed: Feb. 27, 2026

Related U.S. Application Data
(60) Provisional application No. 63/777,262, filed on Mar. 25, 2025.

(51) Int. Cl. H03M 13/13; H04L 1/00

(52) U.S. Cl. CPC H03M 13/13; H04L 1/0041; H04L 1/0057

(57) ABSTRACT

Error correction performance of polar codes is improved by altering the constructions of information and frozen sets, by swapping indices from the information set with the indices from the frozen set based on entropy-based metrics. A set of pre-calculated entropy values, and a fitness value determined based on the set of pre-calculated entropy values, are used to identify a bit index for a most reliable bit in the information set based on a reliability metric and identify a bit index in the frozen set that results in a reduced entropy metric when swapped with the bit index for the most reliable bit in the information set. The identification and swapping iteratively proceeds at least until a defined number of information bit indices have been considered for swapping.

### CROSS-REFERENCE TO RELATED APPLICATION(S) AND CLAIM OF PRIORITY

This application claims priority under 35 U.S.C. § 119(e) to U.S. Provisional Patent Application No. 63/777,262 filed on Mar. 25, 2025. The above-identified provisional patent applications are hereby incorporated by reference in their entirety.

### TECHNICAL FIELD

This disclosure relates generally to wireless networks. More specifically, this disclosure relates to polar code designs for wireless communications.

### BACKGROUND

The demand of wireless data traffic is rapidly increasing due to the growing popularity among consumers and businesses of smart phones and other mobile data devices, such as tablets, “note pad” computers, net books, eBook readers, and machine type of devices. In order to meet the high growth in mobile data traffic and support new applications and deployments, improvements in radio interface efficiency and coverage are of paramount importance.

To meet the demand for wireless data traffic having increased since deployment of 4G communication systems, and to enable various vertical applications, 5G communication systems have been developed and are currently being deployed. The enablers for the 5G/NR mobile communications include massive antenna technologies, from legacy cellular frequency bands up to high frequencies, to provide beamforming gain and support increased capacity, new waveforms (e.g., new radio access technologies (RATs)) to flexibly accommodate various services/applications with different requirements, new multiple access schemes to support massive connections, etc.

### SUMMARY

This disclosure provides apparatuses and methods for polar code design and polar encoding.

In a first embodiment, a method performed by an electronic device includes generating a first information set and a first frozen set based on an information size and a code length. The method also includes generating a second information set and a second frozen set based on the first information set, the first frozen set, and a set of entropy-based metrics. The method further includes generating a vector based on the second information set, the second frozen set, and a set of message bits. The method still further includes applying a polar transform to the vector to generate a codeword for transmission.

In a second embodiment, a user equipment includes a transceiver configured to transmit a polar codeword to a base station, and a processor operably coupled to the transceiver, The processor is configured to generate a first information set and a first frozen set based on an information size and a code length. The processor is also configured to generate a second information set and a second frozen set based on the first information set, the first frozen set, and a set of entropy-based metrics. The processor is further configured to generate a vector based on the second information set, the second frozen set, and a set of message bits. The processor is still further configured to apply a polar transform to the vector to generate the polar codeword for transmission.

In a third embodiment, a base station includes a transceiver configured to transmit a polar codeword to a user equipment, and a processor operably coupled to the transceiver, The processor is configured to generate a first information set and a first frozen set based on an information size and a code length. The processor is also configured to generate a second information set and a second frozen set based on the first information set, the first frozen set, and a set of entropy-based metrics. The processor is further configured to generate a vector based on the second information set, the second frozen set, and a set of message bits. The processor is still further configured to apply a polar transform to the vector to generate the polar codeword for transmission.

Any single one or any combination of the following features may be used with the first, second, or third embodiment.

The set of entropy-based metrics may include a set of pre-calculated entropy values and a fitness value determined based on the set of pre-calculated entropy values.

Generation of the second information set and the second frozen set based on the first information set, the first frozen set, and the set of entropy-based metrics may include identifying a bit index for a most reliable bit in the first information set based on a reliability metric, and identifying a bit index in the first frozen set that results in a minimum for one of the entropy-based metrics when swapped with the bit index for the most reliable bit in the first information set.

A first value of the one of the entropy-based metrics may be determined when the bit index in the first frozen set is swapped with the bit index for the most reliable bit in the first information set. The first value for the one of the entropy-based metrics may be compared to a prior minimum value for the one of the entropy-based metrics. Based on determining that the first value is smaller than the prior minimum value, swap of the bit index in the first frozen set with the bit index for the most reliable bit in the first information set to generate an intermediate second information set and an intermediate second frozen set may be confirmed, and the prior minimum value may be updated with the first value.

A bit index for a most reliable bit in the intermediate second information set may be identified based on the reliability metric, and a bit index in the second intermediate frozen set that results in a minimum value for the one of the entropy-based metrics when swapped with the bit index for the most reliable bit in the intermediate second information set may be determined. A second value for the one of the entropy-based metrics when the bit index in the intermediate second frozen set is swapped with the bit index for the most reliable bit in the intermediate second information set may be determined. The second value for the one of the entropy-based metrics may be compared to the prior minimum value for the one of the entropy-based metrics. Based on one of a maximum iteration count, a predetermined reduction in the minimum value for the one of the entropy-based metrics, or determining that the second value is not smaller than the prior minimum value, the intermediate second information set may be set as the second information set and the intermediate second frozen set may be set as the second frozen set.

Generation of the second information set and the second frozen set based on the first information set, the first frozen set, and the set of entropy-based metrics may include obtaining a set of bit error rates at bit indices corresponding to bits in the first information set, and determining a block error rate based on the set of bit error rates at the bit indices corresponding to the bits in the first information set. Entropy values at bit indices corresponding to bits in the frozen set may be decremented. Until a bit index i is equal to the code length, the following may be iteratively performed: initialize the bit index i to 0 and define a temporary value to be initialized to 0; increment the temporary value by an entropy value determined at the bit index I; assign a maximum of 0 and the temporary value to both the entropy value determined at the bit index i and the temporary value; and increment by 1 the bit index i.

A fitness value may be set as a weighted sum of the block error rate and a maximum of entropies determined at bit indices corresponding to bits belonging to the first information set.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of this disclosure and its advantages, reference is now made to the following description, taken in conjunction with the accompanying drawings, in which:

FIG. 1 illustrates an example of a wireless network utilizing polar code designs according to embodiments of the present disclosure;

FIGS. 2A and 2B illustrate example wireless transmit and receive paths for use with polar code designs according to embodiments of the present disclosure;

FIG. 3A illustrates an example UE according to embodiments for use with the polar code designs of the present disclosure;

FIG. 3B illustrates an example gNB for use with polar code designs according to embodiments of the present disclosure;

FIG. 4 illustrates an example polar encoding chain according to embodiments of the present disclosure;

FIG. 5 illustrates an example process for polar encoding in accordance with this disclosure;

FIG. 6 illustrates example pseudocode for revising information and frozen sets in accordance with this disclosure;

FIG. 7 illustrates an example process for creating a second information set and a second frozen set in accordance with this disclosure;

FIG. 8 illustrates an example process for computing a fitness value in accordance with this disclosure;

FIG. 9 illustrates an example process for identifying a frozen bit index to be swapped with the identified information bit index in accordance with this disclosure;

FIG. 10 illustrates another example process for computing a fitness value in accordance with this disclosure;

FIG. 11 illustrates yet another example process for computing a fitness value in accordance with this disclosure; and

FIG. 12 is a comparative plot, in terms of BLER, across different SNRs for 5G polar codes and polar codes according to the present disclosure.

### DETAILED DESCRIPTION

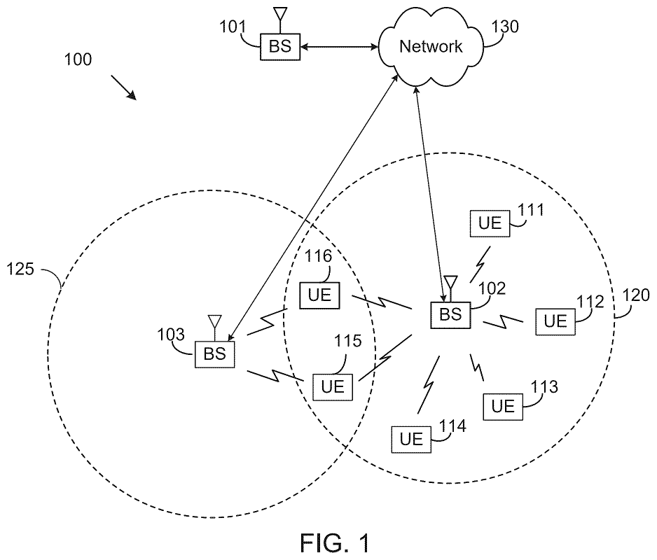

FIGS. 1 through 12, discussed below, and the various embodiments used to describe the principles of this disclosure in this patent document are by way of illustration only and should not be construed in any way to limit the scope of the disclosure. Those skilled in the art will understand that the principles of this disclosure may be implemented in any suitably arranged wireless communication system.

The following documents and standards descriptions are hereby incorporated by reference into the present disclosure as if fully set forth herein:
[1] E. Arikan, “Channel Polarization: A Method for Constructing Capacity-Achieving Codes for Symmetric Binary-Input Memoryless Channels,” in IEEE Transactions on Information Theory, vol. 55, no. 7, pp. 3051-3073, July 2009.

Polar codes with cyclic redundancy check (CRC) bits and successive cancellation list (SCL) decoding exhibit prominent error-correcting performance at short lengths, and accordingly have been adopted as channel codes by the 5th Generation (5G) New Radio (NR) standard to support the transmission of control information. Polar codes with SCL decoding are expected to be adopted by future standards.

The notations used for describing the polar encoding are defined in TABLE 1:

TABLE 1

| Symbol | Definition |
|---|---|
| Z(i) | Reliability of the bit index i, where 0 ≤ i ≤ N − 1. |
| | Z(i) can be calculated by using methods based on density evolution, |
| | Bhattacharyya parameter, Reed-Muller rule and etc. . |
| [symbol] | Information set |
| | A set of bit indices which is defined as a size-K subset of {0,1, ··· , N − 1}. |
| [symbol] | Frozen set |
| | A set of bit indices which defined as [symbol] [symbol] {0, . . . , N − 1}\ [symbol] |
| [symbol] | A subset of b which contains the elements at indices belonging to a set [symbol] , i.e., |
| | [symbol] [symbol] {bᵢ: i ∈ [symbol] }. |

For a polar code with information a size K and a code length N, an information set Q and a frozen set [symbol] are utilized, where Q is a size-K subset of {0, 1, . . . , N−1} and [symbol] ≙{0, . . . , N−1}\Q. The information and frozen sets can be constructed according to methods based on density evolution, Bhattacharyya parameter, Reed-Muller rule and etc.

Based on the information set and the frozen set, information bits a=(a₀, a₁, . . . , a_{K-1}) are mapped to a vector b=(b₀, b₁, . . . , b_{N-1}). The vector b is generated by placing zero bits at indices belonging to the frozen set, i.e., bᵢ=0 for i∈ [symbol] , as well as information bits a at indices belonging to Q, i.e., b_{Q}=a. TABLE 2 illustrates an example of assigning information bits and zero bits to an 8 bit vector b (i.e., N=8), where K=4, Q={3,5,6,7}, and [symbol] ={0,1,2,4}:

TABLE 2

| b₀ | b₁ | b₂ | b₃ | b₄ | b₅ | b₆ | b₇₁ |
|---|---|---|---|---|---|---|---|
| ↑ | ↑ | ↑ | ↑ | ↑ | ↑ | ↑ | ↑ |
| 0 | 0 | 0 | a₀ | 0 | a₁ | a₂ | a₃ |

As shown in TABLE 2, information bits {a₀, a₁, a₂, a₃} and 4 zero bits are mapped to {b₀, b₁, . . . , b₇} in the following manner:

$${b}_{3} = {a}_{0} , {b}_{5} = {a}_{1} , {b}_{6} = {a}_{2} , {b}_{7} = {a}_{3} and$$

$${b}_{0} = {b}_{1} = {b}_{2} = {b}_{4} = 0 .$$

The vector b is mapped into a polar codeword x through the polar transform, defined with the matrix

$${G}_{N} = {[ \begin{matrix}1 & 0 \\ 1 & 1\end{matrix} ]}^{⊗ n} \begin{matrix} \\ \end{matrix}$$

where ⊗ is the Kronecker product, i.e., x=b×G_{N}. The polar codeword x is transmitted through channels.

Although polar codes have proven to be capacity achieving, optimal constructions of information and frozen sets are unknown for polar codes with SCL decoding. For example, when using SCL decoding with list size 8, polar coding still leaves a gap of approximately 1 decibel (dB) from the maximum likelihood (ML) boundary. The present disclosure improves constructions of information and frozen sets by swapping indices from the information set with the indices from the frozen set based on entropy-based metrics, such that the error-correcting performance is enhanced. Benefits of the present disclosure may be achieved by inserting an additional operation into the polar encoding chain, without affecting existing blocks in current, standardized polar coding and decoding processes.

FIGS. 1-3B below describe various embodiments implemented in wireless communications systems and with the use of polar codes. The descriptions of FIGS. 1-3B are not meant to imply physical or architectural limitations to the manner in which different embodiments may be implemented. Different embodiments of the present disclosure may be implemented in any suitably arranged communications system.

FIG. 1 illustrates an example of a wireless network 100 utilizing polar code designs according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the UEs 111-116 include circuitry, programing, or a combination thereof, for polar code designs. In certain embodiments, one or more of the gNBs 101-103 includes circuitry, programing, or a combination thereof, to support polar code designs in a wireless communication system.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

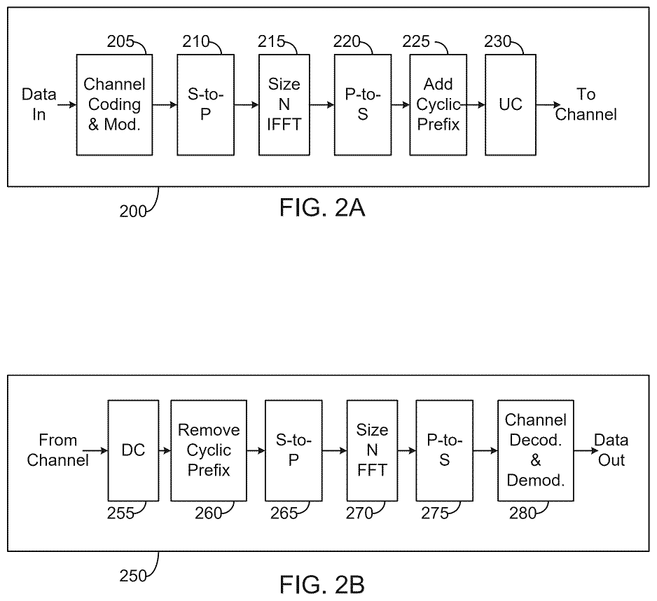

FIGS. 2A and 2B illustrate example wireless transmit and receive paths for use with polar code designs according to embodiments of the present disclosure. In the following description, a transmit path 200 may be described as being implemented in a gNB (such as gNB 102), while a receive path 250 may be described as being implemented in a UE (such as UE 116). However, it will be understood that the receive path 250 can be implemented in a gNB and that the transmit path 200 can be implemented in a UE. In some embodiments, the transmit path 200 and/or the receive path 250 is configured to implement and/or support polar code designs as described in embodiments of the present disclosure.

The transmit path 200 includes a channel coding and modulation block 205, a serial-to-parallel (S-to-P) block 210, a size N Inverse Fast Fourier Transform (IFFT) block 215, a parallel-to-serial (P-to-S) block 220, an add cyclic prefix block 225, and an up-converter (UC) 230. The receive path 250 includes a down-converter (DC) 255, a remove cyclic prefix block 260, a serial-to-parallel (S-to-P) block 265, a size N Fast Fourier Transform (FFT) block 270, a parallel-to-serial (P-to-S) block 275, and a channel decoding and demodulation block 280.

In the transmit path 200, the channel coding and modulation block 205 receives a set of information bits, applies coding (such as a low-density parity check (LDPC) coding or polar coding), and modulates the input bits (such as with Quadrature Phase Shift Keying (QPSK) or Quadrature Amplitude Modulation (QAM)) to generate a sequence of frequency-domain modulation symbols. The serial-to-parallel block 210 converts (such as de-multiplexes) the serial modulated symbols to parallel data in order to generate N parallel symbol streams, where N is the IFFT/FFT size used in the gNB 102 and the UE 116. The size N IFFT block 215 performs an IFFT operation on the N parallel symbol streams to generate time-domain output signals. The parallel-to-serial block 220 converts (such as multiplexes) the parallel time-domain output symbols from the size N IFFT block 215 in order to generate a serial time-domain signal. The add cyclic prefix block 225 inserts a cyclic prefix to the time-domain signal. The up-converter 230 modulates (such as up-converts) the output of the add cyclic prefix block 225 to an RF frequency for transmission via a wireless channel. The signal may also be filtered at baseband before conversion to the RF frequency.

A transmitted RF signal from the gNB 102 arrives at the UE 116 after passing through the wireless channel, and reverse operations to those at the gNB 102 are performed at the UE 116. The down-converter 255 down-converts the received signal to a baseband frequency, and the remove cyclic prefix block 260 removes the cyclic prefix to generate a serial time-domain baseband signal. The serial-to-parallel block 265 converts the time-domain baseband signal to parallel time domain signals. The size N FFT block 270 performs an FFT algorithm to generate N parallel frequency-domain signals. The parallel-to-serial block 275 converts the parallel frequency-domain signals to a sequence of modulated data symbols. The channel decoding and demodulation block 280 demodulates and decodes the modulated symbols to recover the original input data stream.

Each of the gNBs 101-103 may implement a transmit path 200 that is analogous to transmitting in the downlink to UEs 111-116 and may implement a receive path 250 that is analogous to receiving in the uplink from UEs 111-116. Similarly, each of UEs 111-116 may implement a transmit path 200 for transmitting in the uplink to gNBs 101-103 and may implement a receive path 250 for receiving in the downlink from gNBs 101-103.

Each of the components in FIGS. 2A and 2B can be implemented using only hardware or using a combination of hardware and software/firmware. As a particular example, at least some of the components in FIGS. 2A and 2B may be implemented in software, while other components may be implemented by configurable hardware or a mixture of software and configurable hardware. For instance, the FFT block 270 and the IFFT block 215 may be implemented as configurable software algorithms, where the value of size N may be modified according to the implementation.

Furthermore, although described as using FFT and IFFT, this is by way of illustration only and should not be construed to limit the scope of this disclosure. Other types of transforms, such as Discrete Fourier Transform (DFT) and Inverse Discrete Fourier Transform (IDFT) functions, can be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 2A and 2B illustrate examples of wireless transmit and receive paths, various changes may be made to FIGS. 2A and 2B. For example, various components in FIGS. 2A and 2B can be combined, further subdivided, or omitted, and additional components can be added according to particular needs. Also, FIGS. 2A and 2B are meant to illustrate examples of the types of transmit and receive paths that can be used in a wireless network. Any other suitable architecture can be used to support wireless communications in a wireless network.

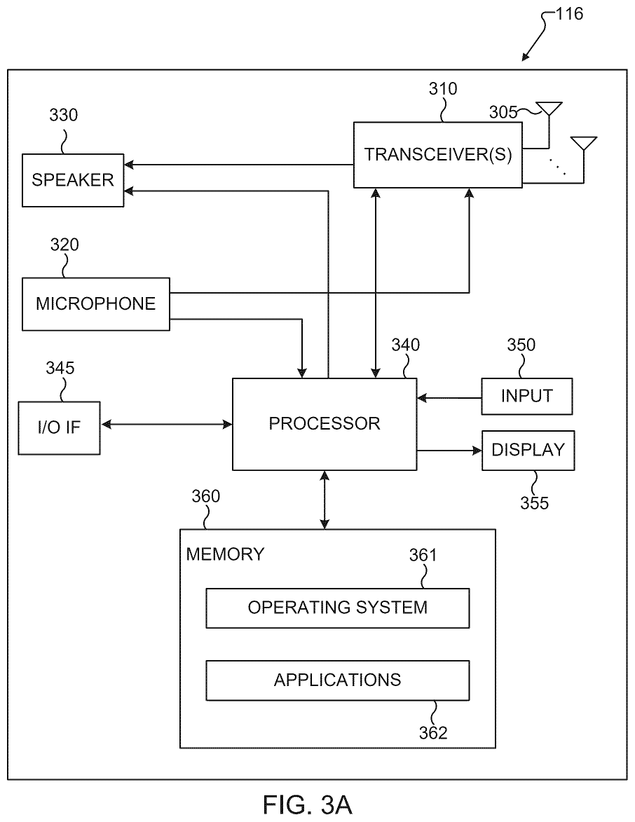

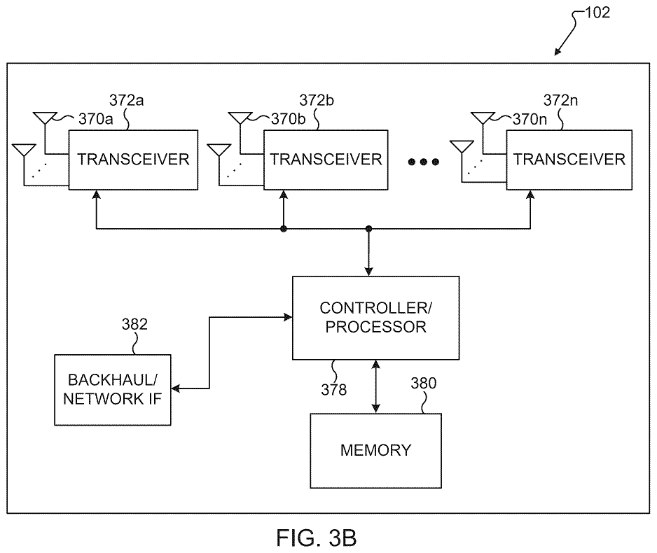

FIG. 3A illustrates an example UE 116 according to embodiments for use with the polar code designs of the present disclosure. The embodiment of the UE 116 illustrated in FIG. 3A is for illustration only, and the UEs 111-115 of FIG. 1 could have the same or similar configuration. However, UEs come in a wide variety of configurations, and FIG. 3A does not limit the scope of this disclosure to any particular implementation of a UE.

As shown in FIG. 3A, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives, from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360, for example, processes for polar coding or decoding as discussed in greater detail below. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3A illustrates one example of UE 116, various changes may be made to FIG. 3A. For example, various components in FIG. 3A could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3A illustrates the UE 116 configured as a mobile telephone or smartphone, UEs could be configured to operate as other types of mobile or stationary devices.

FIG. 3B illustrates an example gNB 102 for use with polar code designs according to embodiments of the present disclosure. The embodiment of the gNB 102 illustrated in FIG. 3B is for illustration only, and the gNBs 101 and 103 of FIG. 1 could have the same or similar configuration. However, gNBs come in a wide variety of configurations, and FIG. 3B does not limit the scope of this disclosure to any particular implementation of a gNB.

As shown in FIG. 3B, the gNB 102 includes multiple antennas 370a-370n, multiple transceivers 372a-372n, a controller/processor 378, a memory 380, and a backhaul or network interface 382.

The transceivers 372a-372n receive, from the antennas 370a-370n, incoming RF signals, such as signals transmitted by UEs in the network 100. The transceivers 372a-372n down-convert the incoming RF signals to generate IF or baseband signals. The IF or baseband signals are processed by receive (RX) processing circuitry in the transceivers 372a-372n and/or controller/processor 378, which generates processed baseband signals by filtering, decoding, and/or digitizing the baseband or IF signals. The controller/processor 378 may further process the baseband signals.

Transmit (TX) processing circuitry in the transceivers 372a-372n and/or controller/processor 378 receives analog or digital data (such as voice data, web data, e-mail, or interactive video game data) from the controller/processor 378. The TX processing circuitry encodes, multiplexes, and/or digitizes the outgoing baseband data to generate processed baseband or IF signals. The transceivers 372a-372n up-converts the baseband or IF signals to RF signals that are transmitted via the antennas 370a-370n.

The controller/processor 378 can include one or more processors or other processing devices that control the overall operation of the gNB 102. For example, the controller/processor 378 could control the reception of uplink (UL) channel signals and the transmission of downlink (DL) channel signals by the transceivers 372a-372n in accordance with well-known principles. The controller/processor 378 could support additional functions as well, such as more advanced wireless communication functions. For instance, the controller/processor 378 could support beam forming or directional routing operations in which outgoing/incoming signals from/to multiple antennas 370a-370n are weighted differently to effectively steer the outgoing signals in a desired direction. Any of a wide variety of other functions could be supported in the gNB 102 by the controller/processor 378.

The controller/processor 378 is also capable of executing programs and other processes resident in the memory 380, such as an OS and, for example, processes to support polar code designs as discussed in greater detail below. The controller/processor 378 can move data into or out of the memory 380 as required by an executing process.

The controller/processor 378 is also coupled to the backhaul or network interface 382. The backhaul or network interface 382 allows the gNB 102 to communicate with other devices or systems over a backhaul connection or over a network. The interface 382 could support communications over any suitable wired or wireless connection(s). For example, when the gNB 102 is implemented as part of a cellular communication system (such as one supporting 5G/NR, LTE, or LTE-A), the interface 382 could allow the gNB 102 to communicate with other gNBs over a wired or wireless backhaul connection. When the gNB 102 is implemented as an access point, the interface 382 could allow the gNB 102 to communicate over a wired or wireless local area network or over a wired or wireless connection to a larger network (such as the Internet). The interface 382 includes any suitable structure supporting communications over a wired or wireless connection, such as an Ethernet or transceiver.

The memory 380 is coupled to the controller/processor 378. Part of the memory 380 could include a RAM, and another part of the memory 380 could include a Flash memory or other ROM.

Although FIG. 3B illustrates one example of gNB 102, various changes may be made to FIG. 3B. For example, the gNB 102 could include any number of each component shown in FIG. 3B. Also, various components in FIG. 3B could be combined, further subdivided, or omitted, and additional components could be added according to particular needs.

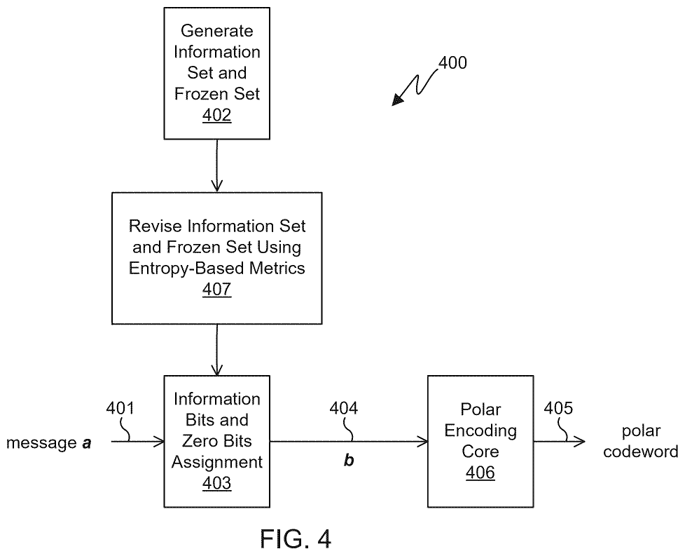

FIG. 4 illustrates an example polar encoding chain 400 according to embodiments of the present disclosure. The polar encoding chain 400 depicted in FIG. 4 is for illustration only. Different embodiments of polar encoding architectures could be used without departing from the scope of this disclosure. The polar encoding chain 400 may be used in conjunction with the transmit path 200 of FIG. 2A, for example with the polar codewords included as at least part of the data supplied to the channel coding and modulation block 205.

In the example of FIG. 4, the polar encoding chain 400 receives message bits 401, such as message a=(a₀, a₁, . . . , a_{K-1}), and generates (in block 402), information set Q and frozen set [symbol] for use in polar encoding of the message bits 401 by assignment (in block 403) of the information bits and zero bits. For example, in block 402, Q may be a K-element subset of {0, 1, 2, . . . , N−1} with [symbol] ={0, 1, 2, . . . , N−1}/Q as the complement thereof. The information set Q and the frozen set [symbol] may be generated by using any of multiple differ methods, e.g., with nested sequence, etc. The output 404 (e.g., vector b) of block 403 is obtained by placing zero bits at the bit indices belonging to [symbol] , i.e., bᵢ=0, i∈ [symbol] , as well as information bits at the bit indices belonging to Q, i.e., b_{Q}=a. The output 404 is mapped to the polar codeword 405 (e.g., x=(x₀, x₁, . . . , x_{N-1})) by a polar encoding core 406 in the manner described above in connection with TABLE 2 (i.e., using the generator matrix

$${G}_{N} = {[ \begin{matrix}1 & 0 \\ 1 & 1\end{matrix} ]}^{⊗ n} with x = b \times {G}_{N} ) .$$

The performance of polar codes depends on the design of the information set 2 and the frozen set [symbol] . Accordingly, in the present disclosure an operation (in block 407) is introduced for revision of the information set 2 and the frozen set [symbol] using entropy-based metrics. The output of revised information set Q′ and the frozen set [symbol] ′ are then assigned in block 403.

Although FIG. 4 illustrates one example of polar encoding chain 400, various changes may be made to FIG. 4. For example, the polar encoding chain 400 could include any number of each component shown in FIG. 4, and various additional component(s) may be introduced. Also, various components in FIG. 4 could be combined, further subdivided, or omitted, and additional components could be added according to particular needs.

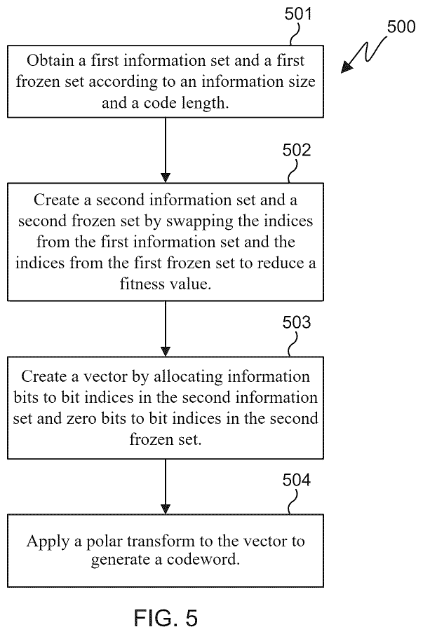

FIG. 5 illustrates an example process 500 for polar encoding in accordance with this disclosure. For ease of explanation, the process 500 of FIG. 5 is described as being performed in connection with the transmit path 200 of FIG. 2A implemented within either a gNB (such as gNB 102) or a UE (such as UE 116) in the wireless network 100 of FIG. 1. However, the process 500 may be performed using any other suitable device(s) and in any other suitable system(s).

As shown in FIG. 5, the process 500 includes (step 501), for a polar code with an information size K and a code length N (which may optionally be limited to some combination of 64, 128, 256, and/or 1024), obtaining a first information set Q and a first frozen set [symbol] , where Q is a size-K subset of {0, 1, . . . , N−1} and [symbol] ≙{0, . . . , N−1}\Q. The first information set Q and the first frozen set [symbol] can be constructed according to methods based on density evolution, Bhattacharyya parameter, Reed-Muller rule, etc.

In the process 500, a subset of the first information set Q is denoted [symbol] and a subset of the first frozen set [symbol] is denoted [symbol] (step 502). [symbol] and [symbol] are swapped to create a second information set, denoted Q′, and a second frozen set, denoted [symbol] ′, i.e., Q′=(Q\ [symbol] )∪ [symbol] and [symbol] ′=( [symbol] \ [symbol] )∪ [symbol] . The resulting (Q′, [symbol] ′) derives an entropy-based fitness value smaller than that derived by (Q, [symbol] ). One embodiment for creating the second information set and the second frozen set is described in further detail below.

Information bits a=(a₀, a₁, . . . , a_{K-1}) are mapped to a vector b=(b₀, b₁, . . . , b_{N-1}) based on the second information set Q′ and the second frozen set [symbol] (step 503). The vector b is generated by placing zero bits at bit indices belonging to the second frozen set, i.e., bᵢ=0, i∈ [symbol] ′, as well as information bits a at bit indices belonging to the second information set, i.e., b_{Q′}=a.

The vector b is mapped to x through the generator matrix

$${G}_{N} = {[ \begin{matrix}1 & 0 \\ 1 & 1\end{matrix} ]}^{⊗ n} ,$$

i.e., x=b×G_{N}, where ⊗ is the Kronecker product. x is the codeword to be transmitted through channels (step 504).

Although FIG. 5 illustrates one example of a process 500 for polar encoding, various changes may be made to FIG. 5. For example, while shown as a series of steps, various steps in FIG. 5 could overlap, occur in parallel, occur in a different order, or occur any number of times (including zero times).

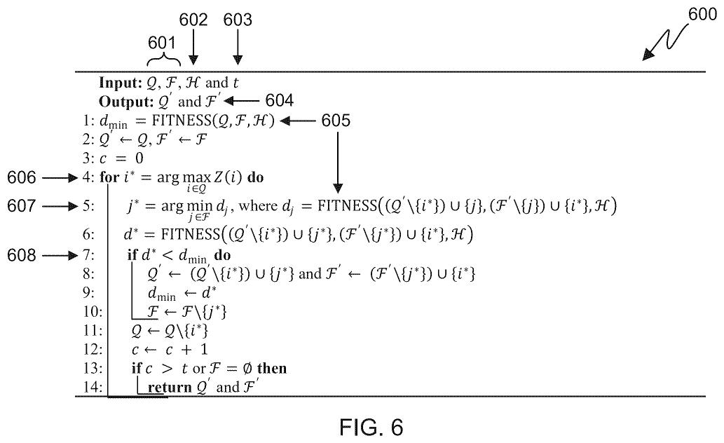

FIG. 6 illustrates example pseudocode 600 for revising information and frozen sets in accordance with this disclosure. For ease of explanation, the pseudocode 600 of FIG. 6 is described as implemented for step 502 within the process 500 of FIG. 5. However, the pseudocode 600 could be employed within any other suitable process.

In the example shown, the pseudocode 600 receives as inputs two information sets 601 that only contain the bit indices that have not been swapped—that is, a first information set Q and a first frozen set F. The pseudocode 600 also receives as inputs a set 602 of entropy values (H), which can be precalculated, and a parameter 603 (t) that specifies the number of information bit indices considered for swapping, which governs the complexity-performance trade-off. The output of the pseudocode 600 is also two information sets

The segment 606 of the pseudocode 600 that starts at line 4 identifies the most reliable bit index in the information set for potential swapping, where Z(i) denotes a reliability metric. The segment 607 of the pseudocode 600 that starts at line 5 identifies the bit index in the frozen set that leads to the minimum fitness value when swappers with the most-reliable information bit index. In the segment 608 of the pseudocode 600 that starts at line 7, if the new smallest fitness value is smaller than a temporary smallest value, the swap is confirmed.

Although FIG. 6 illustrates one example of pseudocode 600 for revising information and frozen sets, various changes may be made to FIG. 6 For example, while shown as a series of functions and commands, various portions of FIG. 6 could be altered, and various other functions or commands included.

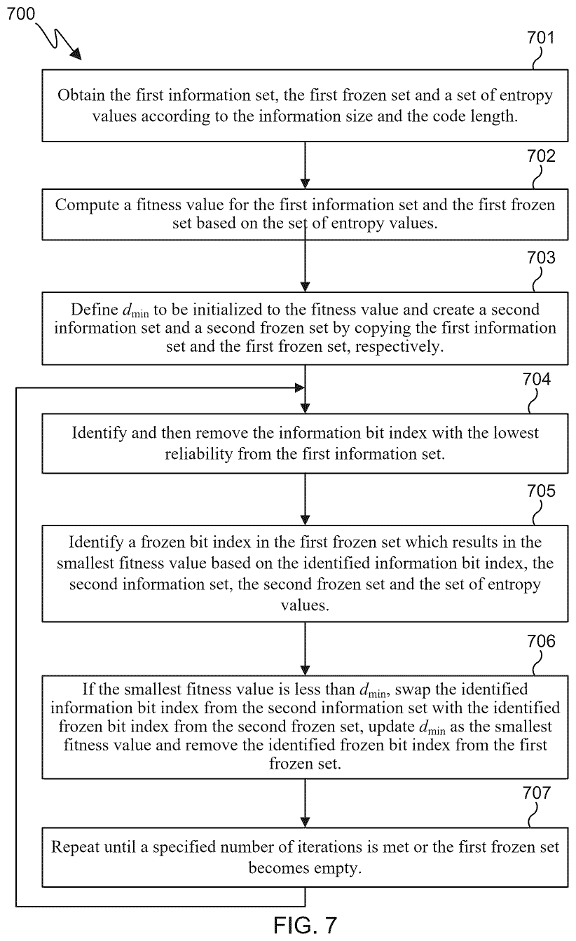

FIG. 7 illustrates an example process 700 for creating a second information set and a second frozen set in accordance with this disclosure. For ease of explanation, the process 700 of FIG. 7 is described as being performed in accordance with the pseudocode 600 of FIG. 6, as part of step 502 in FIG. 5. However, the process 700 may be performed using any other suitable programming and in any other suitable process.

As shown in FIG. 7, the process 700 includes obtaining the first information set, the first frozen set and a set of entropy values according to the information size and the code length (step 701). The first information set Q and the first frozen set [symbol] are obtained and a set containing N entropy values, denoted [symbol] ≙{H₀, H₁, . . . , H_{N-1}}, are obtained. One embodiment for generating [symbol] is according to density evolution via Gaussian approximation (DEGA). An example set of entropy values for N=128 obtained by performing DEGA at a signal-to-noise ratio (SNR) of −1 decibels (dB) is given by

$$ℋ = \{ 0.989477098 , 0.979105592 , 0.989301503 , 0.958776474 , \\ 0.989476919 , 0.978496671 , 0.987506032 , 0.906632841 , 0.989477158 , \\ 0.978897572 , 0.988489449 , 0.928779364 , 0.988250852 , 0.922686934 , \\ 0.894814968 , 0.491336972 , 0.9894768 , 0.978364408 , 0.987209916 , \\ 0.901084185 , 0.985698521 , 0.877082467 , 0.828258097 , 0.372704595 , \\ 0.977829874 , 0.796892762 , 0.72184509 , 0.247750968 , 0.60550034 , \\ 0.157196507 , 0.105266161 , \\ 0.003830004 , 0.989467621 , 0.974599481 , \\ 0.979857922 , 0.81372565 , 0.970582962 , 0.747232854 , 0.660923779 , \\ 0.19597429 , 0.941054165 , 0.616412342 , 0.513929963 , 0.106330067 , \\ 0.392344475 , 0.05800467 , 0.035091288 , 0.000453188 , \\ 0.868485928 , 0.438647658 , 0.338314533 , 0.042106483 , 0.239485264 , \\ 0.020360056 , 0.011516224 , 5.1919 e - 05 , 0.156704962 , \\ 0.008541183 , 0.00450785 , 8.35545 e - 06 , 0.002449418 , \\ 2.52435 e - 06 , 1.17238 e - 06 , 1.14838 e - 26 , 0.989190102 , \\ 0.952827215 , 0.942419171 , 0.621131539 , 0.901980698 , 0.507468045 , \\ 0.403428853 , 0.061655201 , 0.81762886 , 0.357472152 , 0.265752256 , \\ 0.025282737 , 0.184899136 , 0.011960188 , 0.006381094 , \\ 1.64458 e - 05 , 0.682418168 , 0.213018 , 0.14735359 , \\ 0.007540122 , 0.094878808 , 0.003012352 , 0.001639535 , \\ 9.51222 e - 07 , 0.055000152 , 0.001034511 , 0.000557296 , \\ 4.92802 e - 09 , 0.000297494 , 1.20674 e - 10 , \\ 1.50407 e - 11 , 0 , 0.51654309 , 0.107588731 , 0.070534773 , \\ 0.001679717 , 0.040410973 , 0.000596227 , 0.000319766 , \\ 1.87222 e - 10 , 0.021608617 , 0.000176574 , 9.39378 e - 05 , \\ 7.87598 e - 14 , 4.96598 e - 05 , 1.16694 e - 15 , \\ 1.20534 e - 16 , 0 , 0.011824183 , 5.46486 e - 05 , \\ 2.88982 e - 05 , 3.01698 e - 17 , 1.52033 e - 05 , 3.6599 e - 19 , \\ 3.48216 e - 20 , 0 , 7.96487 e - 06 , 4.02443 e - 21 , \\ 3.69755 e - 22 , 0 , 3.3353 e - 23 , 0 , 7.49325 e - 26 , 0 \} ,$$

where e is Euler's number. A table of [symbol] for multiple values of N (e.g., N∈{64,128,256,1024}) for can be specified for multiple SNRs, through signaling between transmitter and receiver.

In the process 700, a fitness value, denoted FITNESS (Q, [symbol] , [symbol] ), is calculated for the first information set Q and the first frozen set [symbol] based on the set [symbol] of entropy values (step 702). One embodiment for calculating FITNESS (Q, [symbol] , [symbol] ) is described in further detail below. An information set and a frozen set with a smaller fitness value is preferred, to improve the performance of the resulting polar codes.

A value dₘᵢₙ is created and initialized to the fitness value FITNESS(Q, [symbol] , [symbol] ) (step 703). In addition, a second information set Q′ and a second frozen set [symbol] are created and initialized to the first information set Q and the first frozen set [symbol] , respectively (i.e., Q′←Q and [symbol] ← [symbol] ).

The information bit index having the lowest reliability within the first information set 2, denoted

$${i}^{*} = arg {min}_{i ∈ 𝒬} Z ( i ) ,$$

is identified (step 704). The identified information bit index is used for swapping with a frozen bit index. Then, the first information set 2 is updated by excluding i*, i.e., Q←Q\{i}.

A frozen bit index j* in the first frozen set [symbol] is identified (step 705). Swapping j* from the second frozen set [symbol] with i* from the second information set Q′ should result in the smallest fitness value, compared with swapping j∈ [symbol] \{j*} with i*. One embodiment for identifying the frozen bit index j* based on i*, Q′, [symbol] and [symbol] is described in further detail below.

If the smallest fitness value, i.e., FITNESS(Q′\{i*})∪{j*}, ( [symbol] ′\{j*})∪{i*}, [symbol] ), is less than dₘᵢₙ, the value of dₘᵢₙ is updated as the smallest fitness value, i.e., dₘᵢₙ←FITNESS(Q′\{i*})∪{j*}, ( [symbol] \{j*})∪{i*}, [symbol] ) (step 706). In addition, the second information set and the second frozen set are updated by swapping i* and j*, i.e., Q′←(Q′\{i*})∪{j*} and [symbol] ←( [symbol] \{j*})∪{i*}, and the identified frozen bit index j* is excluded from the first frozen set [symbol] , i.e., [symbol] ← [symbol] \{j*}.

Based on the operations Q←Q\{i*} (in step 704) and [symbol] ← [symbol] \{j*} (in step 706), an information bit index can be swapped with a frozen bit index by at most one time.

The operations corresponding to steps 704 through 706 are repeated until a specified number of iterations, denoted t∈[0, 1, . . . , K−1], is met or the first frozen set becomes empty. By using different values of t, the number of information bit indices to be swapped through the operations of steps 704 through 706 can be specified to t.

Although FIG. 7 illustrates one example of a process 700 for creating a second information set and a second frozen set, various changes may be made to FIG. 7. For example, while shown as a series of steps, various steps in FIG. 7 could overlap, occur in parallel, occur in a different order, or occur any number of times (including zero times).

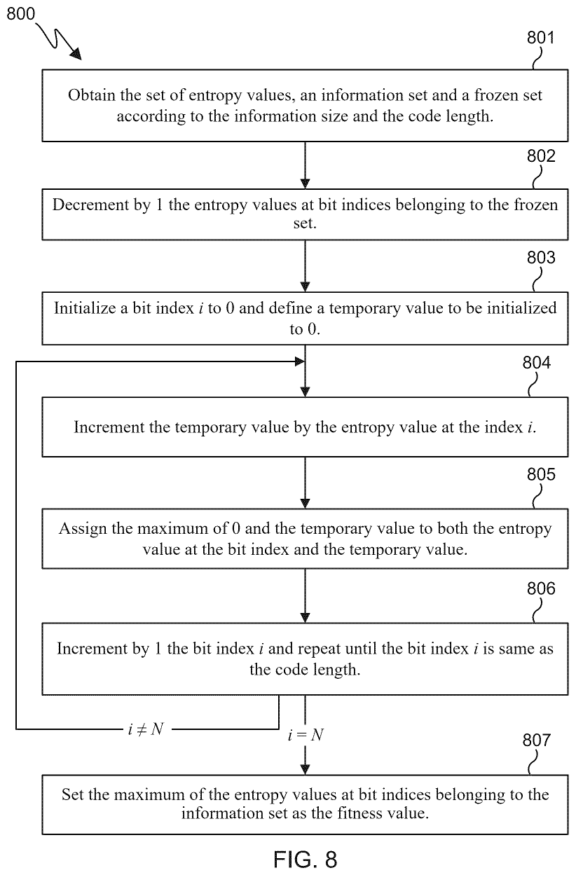

FIG. 8 illustrates an example process 800 for computing a fitness value in accordance with this disclosure. For ease of explanation, the process 800 of FIG. 8 is described as being performed in accordance with the pseudocode 600 of FIG. 6, as part of step 702 in FIG. 7. However, the process 800 may be performed using any other suitable programming and in any other suitable process.

The process 800 may be employed for step 702 of FIG. 7, to compute a fitness value for any information set and frozen set, e.g., (Q, [symbol] ) or (Q′, [symbol] ), based on the set of entropy values.

For a polar code with the information size K and the code length N, an information set Q″ and a frozen set [symbol] are obtained (step 801), where Q″ is a size-K subset of {0, 1, . . . , N−1} and [symbol] ≙{0, . . . , N−1}\Q″. In addition, the set [symbol] of entropy values for the code length N may be obtained, for example, as described for step 701 in FIG. 7.

The set of entropy values are updated by subtracting 1 from the entropy values whose bit indices belong to the frozen set, i.e., Hᵢ←Hᵢ−1 for i∈ [symbol] (step 802). The entropy values at bit indices belonging to the information set Q″ remain unchanged.

A temporary value, denoted d, is initialized to 0 to store the accumulated entropy values (step 803). The accumulation procedure starts from the first entropy value, and hence the bit index i is initialized to 0. The temporary value d is incremented by adding the entropy value at the index i, i.e., d←d+Hᵢ (step 804). If the temporary value d is less than 0, both the entropy value at the bit index i and the temporary value are set to 0; otherwise both are set to the temporary value, i.e., d=Hᵢ←max{0,d} (step 805). If the bit index i is smaller than the code length N, the bit index i is incremented by 1 (step 806) for the next iteration of steps 804 and 805. Hence, Hᵢ can be updated from the bit index 0 to the bit index N−1 recursively by iteratively applying steps 804 and 805.

The fitness value for the information set Q″ and the frozen set [symbol] is equal to the maximum of the entropy values whose indices belong to the information set, i.e.,

$$FITNESS ( {𝒬}^{″} , {ℱ}^{″} , ℋ ) = {max}_{i ∈ {𝒬}^{″}} {H}_{i} ( step 807 ) .$$

Although FIG. 8 illustrates one example of a process 800 for computing a fitness value, various changes may be made to FIG. 8. For example, while shown as a series of steps, various steps in FIG. 8 could overlap, occur in parallel, occur in a different order, or occur any number of times (including zero times).

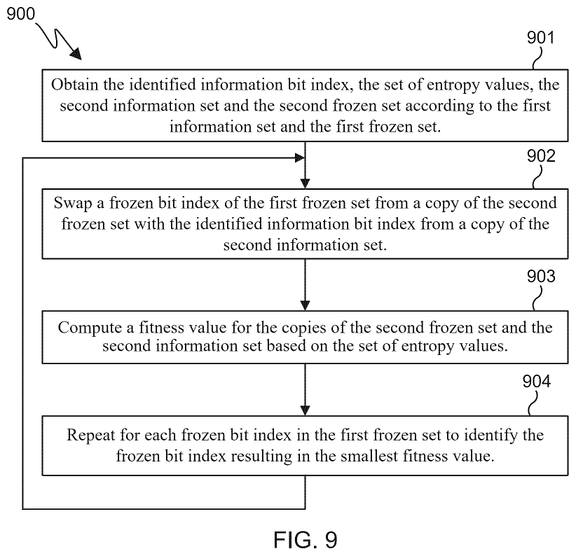

FIG. 9 illustrates an example process 900 for identifying a frozen bit index to be swapped with the identified information bit index in accordance with this disclosure. For ease of explanation, the process 900 of FIG. 9 is described as being performed in accordance with the pseudocode 600 of FIG. 6, as part of step 705 in FIG. 7. However, the process 900 may be performed using any other suitable programming and in any other suitable process.

The process 900 may be employed for step 705 of FIG. 7, to identify a frozen bit index for to be swapped with the identified information bit index.

The identified information bit index i*, the set [symbol] of entropy values, the second information set Q′ and the second frozen set [symbol] are obtained according to the first information set Q and the first frozen set [symbol] (step 901).

$${𝒬}_{copy}^{′} and {ℱ}_{copy}^{′}$$

denote a copy of Q′ and [symbol] , respectively.

$${𝒬}_{copy}^{′} and {ℱ}_{copy}^{′}$$

are updated by swapping a frozen bit index j of the first frozen set with the identified information bit index, i.e.,

$${𝒬}_{copy}^{′} ← ( {𝒬}_{copy}^{′} \backslash \{ {i}^{*} \} ) ⋃ \{ j \} and {ℱ}_{copy}^{′} ← ( {ℱ}_{copy}^{′} \backslash \{ j \} ) ⋃ \{ {i}^{*} \}$$

where j∈ [symbol] (step 902). A fitness value for

$${𝒬}_{copy}^{′} and {ℱ}_{copy}^{′}$$

based the set [symbol] of entropy values can be computed and denoted as

$$FITNESS ( {𝒬}_{copy}^{′} , {ℱ}_{copy}^{′} , ℋ ) ( step 903 ) .$$

One embodiment for computing

$$FITNESS ( {𝒬}_{copy}^{′} , {ℱ}_{copy}^{′} , ℋ )$$

is according to the process 800 of FIG. 8.

The operations of steps 902 and 903 are repeated to compute a fitness value for each frozen bit index in the first frozen set (step 904). Then, the frozen bit index, denoted j*, resulting in the smallest fitness value, denoted d*, can be identified.

The operations of steps 902 and 903 may be summarized as follows:

$${j}^{*} = arg {min}_{j ∈ ℱ} {d}_{j} , where {d}_{j} = FITNESS ( ( {𝒬}^{′} \backslash \{ {i}^{*} \} ) ⋃ \{ j \} , ( {ℱ}^{′} \backslash \{ j \} ) ⋃ \{ {i}^{*} \} , ℋ ) ,$$

$$and$$

$${d}^{*} = FITNESS ( ( {𝒬}^{′} \backslash \{ {i}^{*} \} ) ⋃ \{ {j}^{*} \} , ( {ℱ}^{′} \backslash \{ {j}^{*} \} ) ⋃ \{ {i}^{*} \} , ℋ ) .$$

Although FIG. 9 illustrates one example of a process 900 for identifying a frozen bit index, various changes may be made to FIG. 9. For example, while shown as a series of steps, various steps in FIG. 9 could overlap, occur in parallel, occur in a different order, or occur any number of times (including zero times).

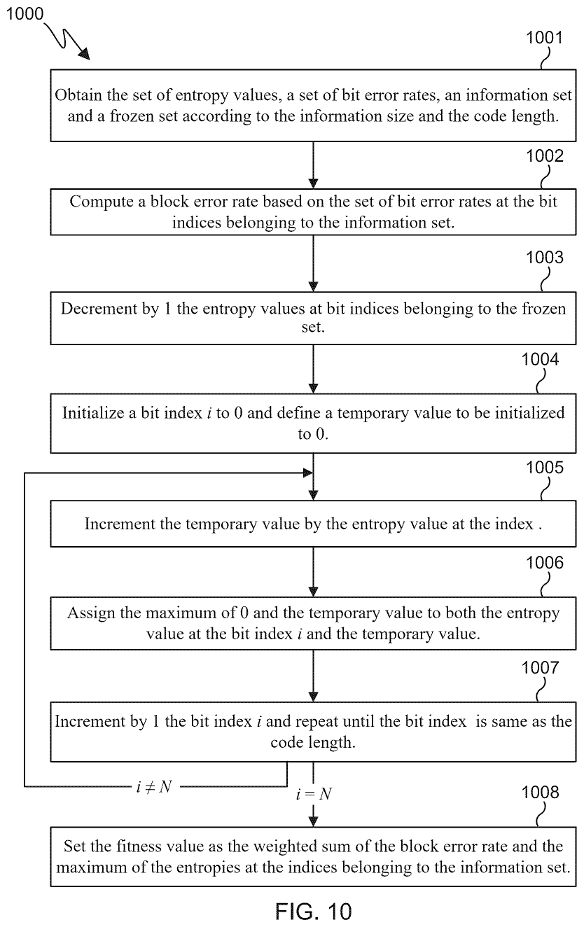

FIG. 10 illustrates another example process 1000 for computing a fitness value in accordance with this disclosure. For ease of explanation, the process 1000 of FIG. 10 is described as being performed in accordance with the pseudocode 600 of FIG. 6, as part of step 702 in FIG. 7 or step 903 in FIG. 9. However, the process 1000 may be performed using any other suitable programming and in any other suitable process.

The process 1000 may be employed for step 702 of FIG. 7 or step 903 of FIG. 9, to compute a fitness value for any information set and frozen set, e.g., (Q, [symbol] ) (in 702) and (Q′, [symbol] ) (in step 903), based on a set of entropy values and a set of bit error rates.

For a polar code with the information size K and the code length N, an information set Q″ and a frozen set [symbol] are obtained (step 1001), where Q″ is a size-K subset of {0, 1, . . . , N−1} and [symbol] ≙{0, . . . , N−1}\Q″. In addition, the set [symbol] of entropy values and a set ε≙{e₀, e₁, . . . , e_{N-1}} of bit error rates (BERs) for the code length N is obtained. One embodiment for generating [symbol] and ε is according to density evolution via Gaussian approximation (DEGA). A table of [symbol] and ε for multiple values of N (e.g., N E {64,128,256,1024}) can be specified for multiple SNRs through signaling between transmitter and receiver.

A block error rate, denoted P, is computed based on the set ε={e₀, e₁, . . . , e_{N-1}} of BERs and the information set Q″ (step 1002). The block error rate represents the probability of at least one information bit being recovered incorrectly, i.e., P=1−Π_{i∈Q″}(1−eᵢ)

The set of entropy values are updated by subtracting 1 from the entropy values whose bit indices belong to the frozen set, i.e., Hᵢ←Hᵢ−1 for i∈ [symbol] (step 1003). The entropy values at bit indices belonging to the information set Q″ remain unchanged.

A temporary value, denoted d, is initialized to 0 to store the accumulated entropy values (step 1004). The accumulation procedure starts from the first entropy value, and hence the bit index i is initialized to 0. The temporary value d is incremented by adding the entropy value at the index i, i.e., d←d+Hᵢ (step 1005). If the temporary value d is less than 0, both the entropy value at the bit index i and the temporary value are set to 0; otherwise both are set to the temporary value, i.e., d=Hᵢ←max{0,d} (step 1006).

If the bit index i is smaller than the code length N, the bit index i is incremented by 1 (step 1007) for the next iteration. Hence, Hᵢ can be updated from the bit index 0 to the bit index N−1 recursively by iteratively applying the operations of steps 1005 and 1006.

The fitness value for the information set and the frozen set is equal to the weighted sum of the block error rate and the maximum of the entropy values whose indices belong to the first information set, i.e.,

$$FITNESS ( {𝒬}^{″} , {ℱ}^{″} , ℋ ) = c \times P + ( 1 - c ) \times {max}_{i ∈ {𝒬}^{″}} {H}_{i} ,$$

where 0≤c≤1 (step 1008).

Although FIG. 10 illustrates one example of a process 1000 for computing a fitness value, various changes may be made to FIG. 10. For example, while shown as a series of steps, various steps in FIG. 10 could overlap, occur in parallel, occur in a different order, or occur any number of times (including zero times).

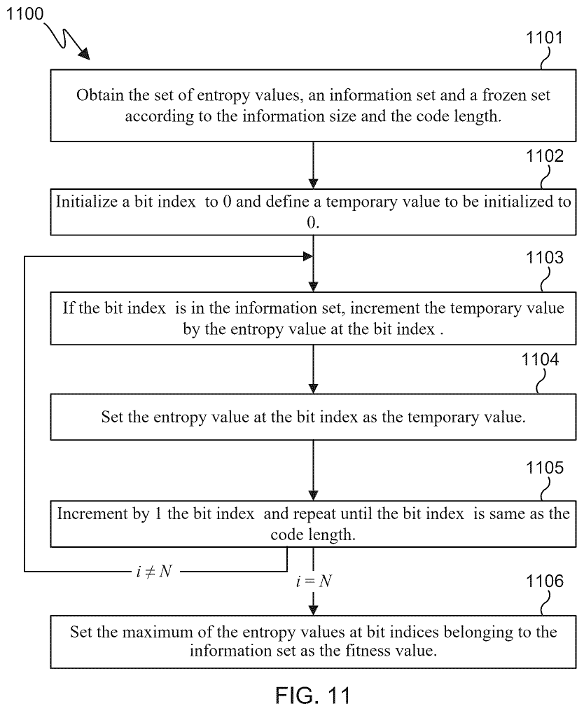

FIG. 11 illustrates yet another example process 1100 for computing a fitness value in accordance with this disclosure. For ease of explanation, the process 1100 of FIG. 11 is described as being performed in accordance with the pseudocode 600 of FIG. 6, as part of step 702 in FIG. 7 or step 903 in FIG. 9. However, the process 1100 may be performed using any other suitable programming and in any other suitable process.

The process 1000 may be employed for step 702 of FIG. 7 or step 903 of FIG. 9, to compute a fitness value for any information set and frozen set, e.g., (Q, [symbol] ) (in step 702) and (Q′, [symbol] ) (in step 903), based on a set of entropy values.

For a polar code with an information size K and a length N, an information set Q′ and a frozen set [symbol] are obtained (step 1101), where Q″ is a size-K subset of {0, 1, . . . , N−1} and [symbol] ≙{0, . . . , N−1}\Q″. In addition, the set [symbol] of entropy values for the code length N is obtained.

A temporary value, denoted d, is initialized to 0 to store the accumulated entropy values (step 1102). The accumulation procedure starts from the first entropy value, and hence the bit index i is initialized to 0.

The accumulation procedure considers the entropy values for the bit indices belonging to the information set (step 1103). Therefore, if the bit index i is in the information set, the temporary value d is incremented by adding the entropy value at the index i, i.e., d←d+Hᵢ if i∈Q″. The entropy value at the bit index i is set to the temporary value d (step 1104).

If the bit index i is smaller than the code length N, the bit index i is incremented by 1 (step 1005) for the next iteration. Hence, Hᵢ can be updated from the bit index 0 to the bit index N−1 recursively by iteratively applying the operations of steps 1103 and 1104.

The fitness value for the information set Q″ and the frozen set [symbol] is equal to the maximum of the entropy values whose indices belong to the information set, i.e.

$$FITNESS ( {𝒬}^{″} , {ℱ}^{″} , ℋ ) = {max}_{i ∈ {𝒬}^{″}} {H}_{i} ( step 1006 ) .$$

Although FIG. 11 illustrates one example of a process 1100 for computing a fitness value, various changes may be made to FIG. 11. For example, while shown as a series of steps, various steps in FIG. 11 could overlap, occur in parallel, occur in a different order, or occur any number of times (including zero times).

In still another embodiment for computing a fitness value, the fitness value for the information set Q′ and the frozen set [symbol] is equal to the weighted summation of the variance and the maximum of the entropy values whose indices belong to the first information set, i.e.,

$$FITNESS ( {𝒬}^{″} , {ℱ}^{″} , ℋ ) = c \times Variance ( \{ {H}_{i} : i ∈ {𝒬}^{″} \} ) + ( 1 - c ) \times {max}_{i ∈ {𝒬}^{″}} {H}_{i} ,$$

where Variance( ) is a statistical measure of the dispersion or spread of data points around their mean, calculated as the average of the squared deviations from the mean, and max( ) determines a maximum. The other operations can be identical or similar to the operations in (for example) the process 800.

The polar codewords described herein may be used for downlink and uplink control information transmission in accordance with any standardized wireless communications.

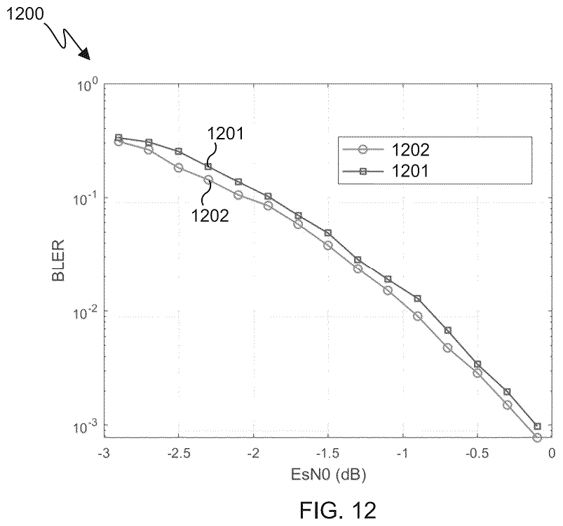

FIG. 12 is a comparative plot 1200, in terms of BLER (plotted logarithmically), across different SNRs (quantified by the symbol energy to noise power spectral density ratio (EsNO) in dB) for 5G polar codes and polar codes according to the present disclosure. The information size and the code length are 40 and 102, respectively. List-8 SCL decoding aided by 11-bit CRC and NR 5G rate matching are both applied, for both traces. As shown by trace 1202, the proposed polar design consistently outperforms NR 5G polar codes (trace 1201) by up to 0.1 dB.

Any of the above variation embodiments can be utilized independently or in combination with at least one other variation embodiment. The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claim scope. The scope of patented subject matter is defined by the claims.

What is claimed is:

1. A method performed by an electronic device, the method comprising:
generating a first information set and a first frozen set based on an information size and a code length;
generating a second information set and a second frozen set based on the first information set, the first frozen set, and a set of entropy-based metrics;
generating a vector based on the second information set, the second frozen set, and a set of message bits; and
applying a polar transform to the vector to generate a polar codeword for transmission.

2. The method of claim 1, wherein the set of entropy-based metrics comprises:
a set of pre-calculated entropy values; and
a fitness value determined based on the set of pre-calculated entropy values.

3. The method of claim 1, wherein generating the second information set and the second frozen set based on the first information set, the first frozen set, and the set of entropy-based metrics comprises:
identifying a bit index for a most reliable bit in the first information set based on a reliability metric; and
identifying a bit index in the first frozen set that results in a minimum for one of the entropy-based metrics when swapped with the bit index for the most reliable bit in the first information set.

4. The method of claim 3, further comprising:
determining a first value of the one of the entropy-based metrics when the bit index in the first frozen set is swapped with the bit index for the most reliable bit in the first information set;
comparing the first value for the one of the entropy-based metrics to a prior minimum value for the one of the entropy-based metrics; and
based on determining that the first value is smaller than the prior minimum value,
confirming the swap of the bit index in the first frozen set with the bit index for the most reliable bit in the first information set to generate an intermediate second information set and an intermediate second frozen set, and
updating the prior minimum value with the first value.

5. The method of claim 4, further comprising:
identifying a bit index for a most reliable bit in the intermediate second information set based on the reliability metric;
identifying a bit index in the second intermediate frozen set that results in a minimum value for the one of the entropy-based metrics when swapped with the bit index for the most reliable bit in the intermediate second information set;
determining a second value for the one of the entropy-based metrics when the bit index in the intermediate second frozen set is swapped with the bit index for the most reliable bit in the intermediate second information set;
comparing the second value for the one of the entropy-based metrics to the prior minimum value for the one of the entropy-based metrics; and
based on one of a maximum iteration count, a predetermined reduction in the minimum value for the one of the entropy-based metrics, or determining that the second value is not smaller than the prior minimum value, setting the intermediate second information set as the second information set and the intermediate second frozen set as the second frozen set.

6. The method of claim 1, wherein generating the second information set and the second frozen set based on the first information set, the first frozen set, and the set of entropy-based metrics comprises:
obtaining a set of bit error rates at bit indices corresponding to bits in the first information set;
determining a block error rate based on the set of bit error rates at the bit indices corresponding to the bits in the first information set;
decrementing entropy values at bit indices corresponding to bits in the frozen set; and
until a bit index i is equal to the code length, iteratively:
initializing the bit index i to 0 and defining a temporary value to be initialized to 0,
incrementing the temporary value by an entropy value determined at the bit index i,
assigning a maximum of 0 and the temporary value to both the entropy value determined at the bit index i and the temporary value, and
incrementing by 1 the bit index i.

7. The method of claim 6, further comprising:
setting a fitness value as a weighted sum of the block error rate and a maximum of entropies determined at bit indices corresponding to bits belonging to the first information set.

8. A user equipment (UE) comprising:
a transceiver configured to transmit a polar codeword to a base station (BS); and
a processor operably coupled to the transceiver, the processor configured to:
generate a first information set and a first frozen set based on an information size and a code length;
generate a second information set and a second frozen set based on the first information set, the first frozen set, and a set of entropy-based metrics;
generate a vector based on the second information set, the second frozen set, and a set of message bits; and
apply a polar transform to the vector to generate the polar codeword for transmission.

9. The UE of claim 8, wherein the set of entropy-based metrics comprises:
a set of pre-calculated entropy values; and
a fitness value determined based on the set of pre-calculated entropy values.

10. The UE of claim 8, wherein the processor is configured to generate the second information set and the second frozen set based on the first information set, the first frozen set, and the set of entropy-based metrics by:
identifying a bit index for a most reliable bit in the first information set based on a reliability metric; and
identifying a bit index in the first frozen set that results in a minimum for one of the entropy-based metrics when swapped with the bit index for the most reliable bit in the first information set.

11. The UE of claim 10, wherein the processor is configured to:
determine a first value of the one of the entropy-based metrics when the bit index in the first frozen set is swapped with the bit index for the most reliable bit in the first information set;
compare the first value for the one of the entropy-based metrics to a prior minimum value for the one of the entropy-based metrics; and
based on determining that the first value is smaller than the prior minimum value,
confirm the swap of the bit index in the first frozen set with the bit index for the most reliable bit in the first information set to generate an intermediate second information set and an intermediate second frozen set, and
update the prior minimum value with the first value.

12. The UE of claim 11, wherein the processor is configured to:
identify a bit index for a most reliable bit in the intermediate second information set based on the reliability metric;
identify a bit index in the second intermediate frozen set that results in a minimum value for the one of the entropy-based metrics when swapped with the bit index for the most reliable bit in the intermediate second information set;
determine a second value for the one of the entropy-based metrics when the bit index in the intermediate second frozen set is swapped with the bit index for the most reliable bit in the intermediate second information set;
compare the second value for the one of the entropy-based metrics to the prior minimum value for the one of the entropy-based metrics; and
based on one of a maximum iteration count, a predetermined reduction in the minimum value for the one of the entropy-based metrics, or determining that the second value is not smaller than the prior minimum value, set the intermediate second information set as the second information set and the intermediate second frozen set as the second frozen set.

13. The UE of claim 8, wherein the processor is configured to generate the second information set and the second frozen set based on the first information set, the first frozen set, and the set of entropy-based metrics by:
obtaining a set of bit error rates at bit indices corresponding to bits in the first information set;
determining a block error rate based on the set of bit error rates at the bit indices corresponding to the bits in the first information set;
decrementing entropy values at bit indices corresponding to bits in the frozen set; and
until a bit index i is equal to the code length, iteratively:
initializing the bit index i to 0 and defining a temporary value to be initialized to 0,
incrementing the temporary value by an entropy value determined at the bit index i,
assigning a maximum of 0 and the temporary value to both the entropy value determined at the bit index i and the temporary value, and
incrementing by 1 the bit index i.

14. The UE of claim 13, wherein the processor is configured to:
set a fitness value as a weighted sum of the block error rate and a maximum of entropies determined at bit indices corresponding to bits belonging to the first information set.

15. A base station (BS) comprising:
a transceiver configured to transmit a polar codeword to a user equipment (UE); and
a processor operably coupled to the transceiver, the processor configured to:
generate a first information set and a first frozen set based on an information size and a code length;
generate a second information set and a second frozen set based on the first information set, the first frozen set, and a set of entropy-based metrics;
generate a vector based on the second information set, the second frozen set, and a set of message bits; and
apply a polar transform to the vector to generate the polar codeword for transmission.

16. The BS of claim 15, wherein the set of entropy-based metrics comprises:
a set of pre-calculated entropy values; and
a fitness value determined based on the set of pre-calculated entropy values.

17. The BS of claim 15, wherein the processor is configured to generate the second information set and the second frozen set based on the first information set, the first frozen set, and the set of entropy-based metrics by:
identifying a bit index for a most reliable bit in the first information set based on a reliability metric; and
identifying a bit index in the first frozen set that results in a minimum for one of the entropy-based metrics when swapped with the bit index for the most reliable bit in the first information set.

18. The BS of claim 17, wherein the processor is configured to:
determine a first value of the one of the entropy-based metrics when the bit index in the first frozen set is swapped with the bit index for the most reliable bit in the first information set;
compare the first value for the one of the entropy-based metrics to a prior minimum value for the one of the entropy-based metrics; and
based on determining that the first value is smaller than the prior minimum value,
confirm the swap of the bit index in the first frozen set with the bit index for the most reliable bit in the first information set to generate an intermediate second information set and an intermediate second frozen set, and
update the prior minimum value with the first value.

19. The BS of claim 18, wherein the processor is configured to:
identify a bit index for a most reliable bit in the intermediate second information set based on the reliability metric;
identify a bit index in the second intermediate frozen set that results in a minimum value for the one of the entropy-based metrics when swapped with the bit index for the most reliable bit in the intermediate second information set;
determine a second value for the one of the entropy-based metrics when the bit index in the intermediate second frozen set is swapped with the bit index for the most reliable bit in the intermediate second information set;
compare the second value for the one of the entropy-based metrics to the prior minimum value for the one of the entropy-based metrics; and
based on one of a maximum iteration count, a predetermined reduction in the minimum value for the one of the entropy-based metrics, or determining that the second value is not smaller than the prior minimum value, set the intermediate second information set as the second information set and the intermediate second frozen set as the second frozen set.

20. The BS of claim 15, wherein the processor is configured to generate the second information set and the second frozen set based on the first information set, the first frozen set, and the set of entropy-based metrics by:
obtaining a set of bit error rates at bit indices corresponding to bits in the first information set;
determining a block error rate based on the set of bit error rates at the bit indices corresponding to the bits in the first information set;
decrementing entropy values at bit indices corresponding to bits in the frozen set; and
until a bit index i is equal to the code length, iteratively:
initializing the bit index i to 0 and defining a temporary value to be initialized to 0,
incrementing the temporary value by an entropy value determined at the bit index i,
assigning a maximum of 0 and the temporary value to both the entropy value determined at the bit index i and the temporary value, and
incrementing by 1 the bit index i.
